(19) United States
(12) Patent Application Publication
(10) Pub. No.: US 2026/0188232 A1
(43) Pub. Date: Jul. 2, 2026

(54) Display Apparatus and Driving Method Thereof

(71) Applicant: LG Display Co., Ltd., Seoul (KR)

(72) Inventors: Young Hyun Ko, Paju-si (KR); Won Sang Ryu, Paju-si (KR)

(21) Appl. No.: 19/435,199

(22) Filed: Dec. 29, 2025

(30) Foreign Application Priority Data
Dec. 31, 2024 (KR) 10-2024-0203034

(51) Int. Cl. G09G 3/3233

(52) U.S. Cl. CPC G09G 3/3233; G09G 2300/0426; G09G 2300/0465; G09G 2300/0842; G09G 2320/043

(57) ABSTRACT

A display apparatus includes a display panel including a subpixel and a driver configured to drive the display panel. The subpixel includes a sensing transistor configured to transfer a reference voltage, applied through a data line, to a second electrode of a capacitor for a first time included in a horizontal period and a switching transistor configured to transfer a data voltage, applied through the data line, to a first electrode of the capacitor for a second time included in the horizontal period.

### CROSS-REFERENCE TO RELATED APPLICATION

This application claims the priority of Republic of Korea Patent Application No. 10-2024-0203034 filed on December 31, 2024, which is incorporated by reference in its entirety.

### BACKGROUND

### Field

The present disclosure relates to a display apparatus and a driving method thereof.

### Description of the Related Art

As information technology advances, the market for display apparatuses which are connection mediums connecting a user with information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

### SUMMARY

The present disclosure may enhance an aperture ratio, based on a subpixel dualizing and receiving a data voltage and a reference voltage through one data line, and thus, may enhance the lifetime and display quality of a display panel. Also, the present disclosure may delay a degradation characteristic of a transistor so that, when one of two transistors is turned on, the other transistor is turned off based on an opposite voltage condition, thereby contributing to enhance a lifetime of a device.

To achieve these objects and other advantages and in accordance with the purpose of the disclosure, as embodied and broadly described herein, a display apparatus includes: a display panel including a subpixel; and a driver configured to drive the display panel, wherein the subpixel includes: a sensing transistor configured to transfer a reference voltage, applied through a data line, to a second electrode of a capacitor for a first time included in a horizontal period; and a switching transistor configured to transfer a data voltage, applied through the data line, to a first electrode of the capacitor for a second time included in the horizontal period.

The sensing transistor may include a first electrode connected to the data line, a gate electrode connected to a first sensing line included in a first gate line, and a second electrode connected to the second electrode of the capacitor, and the switching transistor may include a first electrode connected to the data line, a gate electrode connected to a first scan line included in the first gate line, and a second electrode connected to the first electrode of the capacitor.

The subpixel may further include: a driving transistor including a gate electrode connected to the second electrode of the switching transistor and the first electrode of the capacitor, a first electrode connected to a high-level voltage line, and a second electrode connected to the second electrode of the capacitor and the second electrode of the sensing transistor; and a light emitting diode including an anode electrode connected to the second electrode of the sensing transistor, the second electrode of the driving transistor, and the second electrode of the capacitor and a cathode electrode connected to a low-level voltage line.

The sensing transistor and the switching transistor may have a period where operations opposite to each other are performed in response to a first gate signal applied through the first gate line.

The sensing transistor and the switching transistor may have a period where the sensing transistor and the switching transistor are simultaneously turned off in response to a first gate signal applied through the first gate line.

Each of the sensing transistor and the switching transistor may be implemented as a CMOS type including a PMOS type and an NMOS type. The sensing transistor is implemented as one of the PMOS type and the NMOS type, and the switching transistor is implemented as the other of the PMOS type and the NMOS type.

The sensing transistor may include a first electrode connected to the data line, a gate electrode connected to the first gate line, and a second electrode connected to the second electrode of the capacitor, and the switching transistor may include a first electrode connected to the data line, a gate electrode connected to the first gate line, and a second electrode connected to the first electrode of the capacitor.

The sensing transistor may be turned on based on the first gate signal of a second voltage applied through the first gate line, the switching transistor may be turned on based on the first gate signal of a first voltage applied through the first gate line, the sensing transistor and the switching transistor may be simultaneously turned off based on the first gate signal of a third voltage applied through the first gate line, and the first voltage, the second voltage, and the third voltage may have different levels.

In another aspect of the present disclosure, a driving method of a display apparatus includes: a step of turning on a sensing transistor to transfer a reference voltage, applied through a data line, to a second electrode of a capacitor for a first time included in a horizontal period; a step of turning on a switching transistor to transfer a data voltage, applied through the data line, to a first electrode of the capacitor for a second time included in the horizontal period; and a step of driving a driving transistor, based on a voltage difference between the data voltage stored in the capacitor and the reference voltage, and allowing a light emitting diode to emit light, based on a driving current generated from the driving transistor.

The sensing transistor may include a first electrode connected to the data line, a gate electrode connected to a first sensing line included in a first gate line, and a second electrode connected to the second electrode of the capacitor, and the switching transistor may include a first electrode connected to the data line, a gate electrode connected to a first scan line included in the first gate line, and a second electrode connected to the first electrode of the capacitor.

The sensing transistor may include a first electrode connected to the data line, a gate electrode connected to a first gate line, and a second electrode connected to the second electrode of the capacitor, and the switching transistor may include a first electrode connected to the data line, a gate electrode connected to the first gate line, and a second electrode connected to the first electrode of the capacitor.

The sensing transistor may be turned on based on a first gate signal of a second voltage applied through the first gate line, the switching transistor may be turned on based on the first gate signal of a first voltage applied through the first gate line, the sensing transistor and the switching transistor may be simultaneously turned off based on the first gate signal of a third voltage applied through the first gate line, and the first voltage, the second voltage, and the third voltage may have different levels.

The driving transistor may include a gate electrode connected to the second electrode of the switching transistor and the first electrode of the capacitor, a first electrode connected to a high-level voltage line, and a second electrode connected to the second electrode of the capacitor and the second electrode of the sensing transistor; and the light emitting diode may include an anode electrode connected to the second electrode of the sensing transistor, the second electrode of the driving transistor, and the second electrode of the capacitor and a cathode electrode connected to a low-level voltage line.

The present disclosure may enhance an aperture ratio, based on a subpixel dualizing and receiving a data voltage and a reference voltage through one data line, and thus, may enhance the lifetime and display quality of a display panel. Also, the present disclosure may delay a degradation characteristic of a transistor so that, when one of two transistors is turned on, the other transistor is turned off based on an opposite voltage condition, thereby contributing to enhance a lifetime of a device.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram schematically illustrating a light emitting display apparatus in accordance with one or more embodiments of the present disclosure.

FIGS. 2 and 3 are diagrams for describing a configuration of a gate driver of a gate in panel (GIP) type in accordance with one or more embodiments of the present disclosure.

FIG. 4 is a diagram for describing some of elements of a light emitting display apparatus according to a first embodiment of the present disclosure.

FIG. 5 is a diagram illustrating a circuit configuration of a subpixel according to the first embodiment of the present disclosure.

FIG. 6 is a diagram illustrating a circuit configuration of each of a first subpixel and a second subpixel according to the first embodiment of the present disclosure.

FIG. 7 is a diagram illustrating a driving waveform of each of the first subpixel and the second subpixel illustrated in FIG. 6.

FIGS. 8 and 9 are diagrams illustrating an operating state of the first subpixel, based on the driving waveform illustrated in FIG. 7.

FIG. 10 is a diagram for describing some of elements of a light emitting display apparatus according to a second embodiment of the present disclosure.

FIG. 11 is a diagram illustrating a circuit configuration of a subpixel according to the second embodiment of the present disclosure.

FIG. 12 is a diagram illustrating a circuit configuration of each of a first subpixel and a second subpixel according to the second embodiments of the present disclosure.

FIG. 13 is a diagram illustrating a driving waveform of each of the first subpixel and the second subpixel illustrated in FIG. 12.

FIGS. 14 and 15 are diagrams illustrating an operating state of the first subpixel, based on the driving waveform illustrated in FIG. 13.

FIG. 16 is a diagram for describing a characteristic of a transistor according to the second embodiment of the present disclosure.

FIGS. 17 and 18 are diagrams for describing a modification example of a subpixel according to a third embodiment of the present disclosure.

### DETAILED DESCRIPTION

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

A display apparatus according to the present disclosure may be applied to televisions (TVs), video players, personal computers (PCs), home theaters, electronic devices for vehicles, and smartphones, but is not limited thereto. The display apparatus according to the present disclosure may be implemented as a light emitting display apparatus, a quantum dot display (QDD) apparatus, or a liquid crystal display (LCD) apparatus. Hereinafter, for convenience of description, a light emitting display apparatus self-emitting light by using an inorganic light emitting diode or an organic light emitting diode will be described for example.

Moreover, a transistor described below may be implemented with an n-type transistor, a p-type transistor, or a combination of an n-type transistor and a p-type transistor. A transistor may be a three-electrode element including a gate, a source, and a drain. The source may be an electrode which provides a carrier to a transistor. In the transistor, a carrier may start to flow from the source. The drain may be an electrode where the carrier flows from the transistor to the outside. That is, in the transistor, the carrier flows from the source to the drain.

In the p-type transistor, because a carrier is a hole, a source voltage may be higher than a drain voltage so that the hole flows from the source to the drain. In the p-type transistor, because the hole flows from the source to the drain, a current may flow from the source to the drain. On the other hand, in the n-type transistor, because a carrier is an electron, a source voltage may be lower than a drain voltage so that the electron flows from the source to the drain. In the n-type transistor, because the electron flows from the drain to the source, a current may flow from the drain to the source. However, a source and a drain of a transistor may switch therebetween based on a voltage applied thereto. Based thereon, in the following description, one of a source and a drain will be described as a first electrode, and the other of the source and the drain will be described as a second electrode.

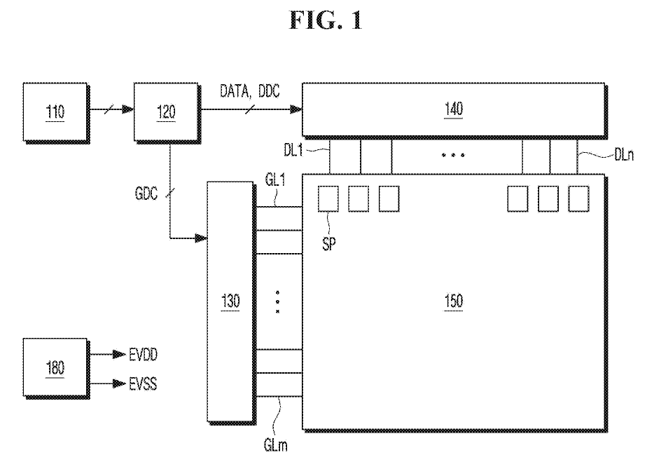

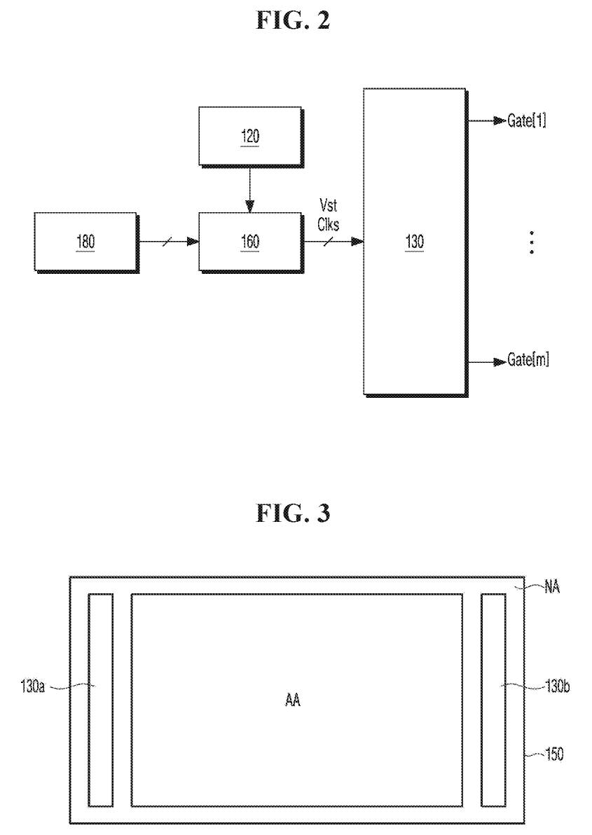

FIG. 1 is a block diagram schematically illustrating a light emitting display apparatus, and FIGS. 2 and 3 are diagrams for describing a configuration of a gate driver of a gate in panel (GIP) type.

As illustrated in FIGS. 1 to 3, a light emitting display apparatus according to one or more embodiments of the present disclosure may include a timing controller (a timing control circuit) 120, a gate driver (a gate driving circuit) 130, a data driver (a data driving circuit) 140, a display panel 150, and a power supply (a power supply circuit) 180.

A video supply unit 110 (a set or a host system) may output a video data signal supplied from the outside or an image data signal stored in an internal memory thereof. The video supply unit 110 may supply a data signal and the various driving signals to the timing controller 120.

The timing controller 120 may output a gate timing control signal GDC for controlling an operation timing of the gate driver 130, a data timing control signal DDC for controlling an operation timing of the data driver 140, and various synchronization signals (a vertical synchronization signal Vsync and a horizontal synchronization signal Hsync). The timing controller 120 may provide the data driver 140 with the data timing control signal DDC and a data signal DATA supplied from the video supply unit 110. The timing controller 120 may be implemented as an integrated circuit (IC) type and may be mounted on a printed circuit board (PCB), but is not limited thereto.

The gate driver 130 may output a gate signal (or a gate voltage) in response to the gate timing control signal GDC supplied from the timing controller 120. The gate driver 130 may supply the gate signal to a plurality of subpixels, included in the display panel 150, through a plurality of gate lines GL1 to GLm. The gate driver 130 may be implemented as an IC type or may be directly provided on the display panel 150 in a GIP type, but is not limited thereto. Hereinafter, for convenience of description, as in FIGS. 2 and 3, a gate driver of a GIP type will be described for example.

The gate driver 130 may include a plurality of shift registers 130a and 130b which are provided as a GIP type at one side and the other side of a non-display area NA of the display panel 150. The shift registers 130a and 130b may be provided as a thin film type in the non- display area NA of the display panel 150, based on a GIP type. The gate driver 130 may output gate signals Gate[1] to Gate[m] for turning on or off transistors formed in a display area AA of the display panel 150.

The gate driver 130 may operate based on signals and voltages output from the timing controller 120, the power supply 180, and a level shifter 160. The level shifter 160 may generate gate control signals needed for driving of the gate driver 130 and the shift registers 130a and 130b, based on the signals and the voltages output from the timing controller 120 and the power supply 180.

In response to the data timing control signal DDC supplied from the timing controller 120, the data driver 140 may sample and latch the data signal DATA, convert a digital data signal into an analog data voltage, based on a gamma reference voltage, and output the analog data voltage. The data driver 140 may respectively supply data voltages to the subpixels of the display panel 150 through a plurality of data lines DL1 to DLn. The data driver 140 may be implemented as an IC type or may be mounted on the display panel 150 or a PCB, but is not limited thereto.

The power supply 180 may generate a high-level voltage and a low-level voltage, based on an external input voltage supplied from the outside, and may output the high-level voltage and the low-level voltage through a high-level voltage line EVDD and a low-level voltage line EVSS. The power supply 180 may generate and output a voltage needed for driving of the gate driver 130 or a voltage needed for driving of the data driver 140, in addition to the high-level voltage and the low-level voltage.

The display panel 150 may be manufactured based on a substrate, having stiffness or flexibility, such as glass, silicone, or polyimide. The display panel 150 may include a plurality of subpixels SP for displaying an image. The subpixel SP may self-emit light toward an upper substrate, a lower substrate, or both the upper substrate and the lower substrate of the display panel 150. The subpixel SP may emit light having one color of red, green, blue, and white. The display panel 150 may display an image, based on a pixel configured with a red subpixel, a green subpixel, and a blue subpixel or a pixel configured with a red subpixel, a green subpixel, a blue subpixel, and a white subpixel.

In the above description, each of the timing controller 120, the gate driver 130, and the data driver 140 has been described as an individual element. However, based on an implementation type of the light emitting display apparatus, one or more of the timing controller 120, the gate driver 130, and the data driver 140 may be integrated into one IC.

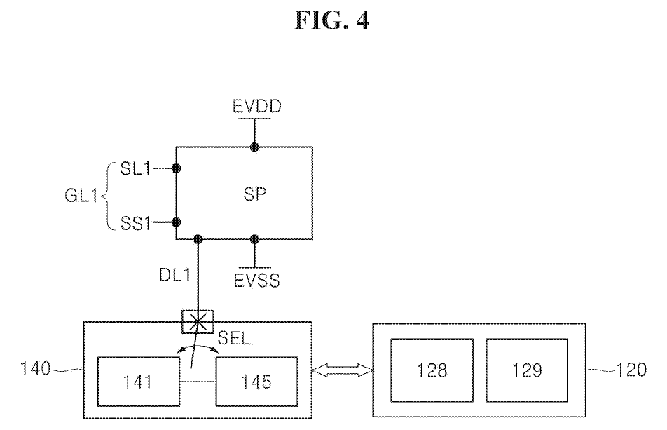

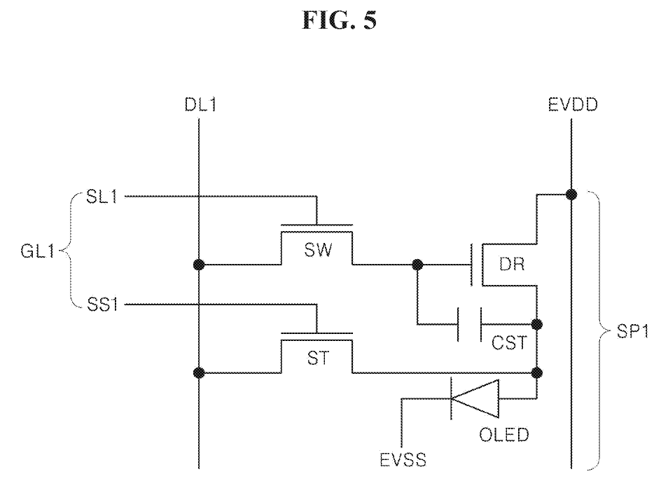

FIG. 4 is a diagram for describing some of elements of a light emitting display apparatus according to a first embodiment of the present disclosure, and FIG. 5 is a diagram illustrating a circuit configuration of a subpixel according to the first embodiment of the present disclosure.

As illustrated in FIG. 4, a subpixel SP according to the first embodiment may be defined by a first gate line GL1 including a first scan line SL1 and a first sensing line SS1, a high-level voltage line EVDD, a low-level voltage line EVSS, and a first data line DL1.

According to the first embodiment, the data driver 140 may include a voltage output circuit 141 which outputs a data voltage which is to be applied to the subpixel SP through the first data line DL1, a pixel sensing circuit 145 which senses elements included in the subpixel SP through the first data line DL1, and a selection switch SEL.

The data driver 140 may control the selection switch SEL so that the first data line DL1 is electrically connected to the voltage output circuit 141, during a general display driving period, and then, may output a data voltage for driving the subpixel SP.

The data driver 140 may control the selection switch SEL so that the first data line DL1 is electrically connected to the pixel sensing circuit 145, during a separately defined sensing driving period, and then, may sense the element included in the subpixel SP to obtain a sensing value. In this case, the sensing value may be obtained as a current value or a voltage value.

The data driver 140 may transfer the sensing value, sensed during the sensing driving period, to the timing controller 120 in conjunction with the timing controller 120. The timing controller 120 may compensate for and output a data signal, based on the sensing value transferred from the data driver 140. To this end, the timing controller 120 may further include a degradation determiner 128 and a degradation compensator 129.

The degradation determiner 128 may determine whether a driving transistor or a light emitting diode is degraded or not, based on the sensing value, and when a degradation occurs, the degradation determiner 128 may output a degradation value. The degradation compensator 129 may calculate a compensation value, based on the degradation value output from the degradation determiner 128, and may reflect a data signal which is to be supplied to the data driver 140.

As illustrated in FIG. 5, a subpixel SP1 according to the first embodiment may include a switching transistor SW, a sensing transistor ST, a driving transistor DR, a capacitor CST, and a light emitting diode OLED.

The switching transistor SW may include a gate electrode connected to a first scan line SL1 included in a first gate line GL1, a first electrode connected to a first data line DL1, and a second electrode connected to a gate electrode of the driving transistor DR and a first electrode of the capacitor CST. The switching transistor SW may be turned on based on a first scan signal applied through the first scan line SL1 and may transfer a data voltage, applied through the first data line DL1, to the first electrode of the capacitor CST.

The sensing transistor ST may include a gate electrode connected to a first sensing line SS1 included in the first gate line GL1, a first electrode connected to the first data line DL1, and a second electrode connected to a second electrode of the driving transistor DR, a second electrode of the capacitor CST, and an anode electrode of the light emitting diode OLED. The sensing transistor ST may be turned on based on a first sensing signal applied through the first sensing line SS1 and may transfer a reference voltage, applied through the first data line DL1, to a sensing node connected to the second electrode of the driving transistor DR, the second electrode of the capacitor CST, and the anode electrode of the light emitting diode OLED. The sensing transistor ST may be turned on to sense a threshold voltage of the driving transistor DR or a threshold voltage of the light emitting diode OLED through the sensing node during a separately defined sensing driving period.

The driving transistor DR may include a gate electrode connected to the second electrode of the switching transistor SW and the first electrode of the capacitor CST, a second electrode connected to a high-level voltage line EVDD, and a second electrode connected to the second electrode of the capacitor CST, the second electrode of the sensing transistor ST, and the anode electrode of the light emitting diode OLED. The driving transistor DR may be turned on based on a data voltage stored in the capacitor CST and may generate a driving current.

The capacitor CST may include the first electrode connected to the second electrode of the switching transistor SW and the gate electrode of the driving transistor DR and the second electrode connected to the second electrode of the driving transistor DR, the second electrode of the sensing transistor ST, and the anode electrode of the light emitting diode OLED. The capacitor CST may apply the data voltage, stored therein, to the gate electrode of the driving transistor DR.

The light emitting diode OLED may include the anode electrode connected to the second electrode of the capacitor CST, the second electrode of the sensing transistor ST, and the second electrode of the driving transistor DR and a cathode electrode connected to a low-level voltage line EVSS. The light emitting diode OLED may emit light, based on the driving current generated from the driving transistor DR.

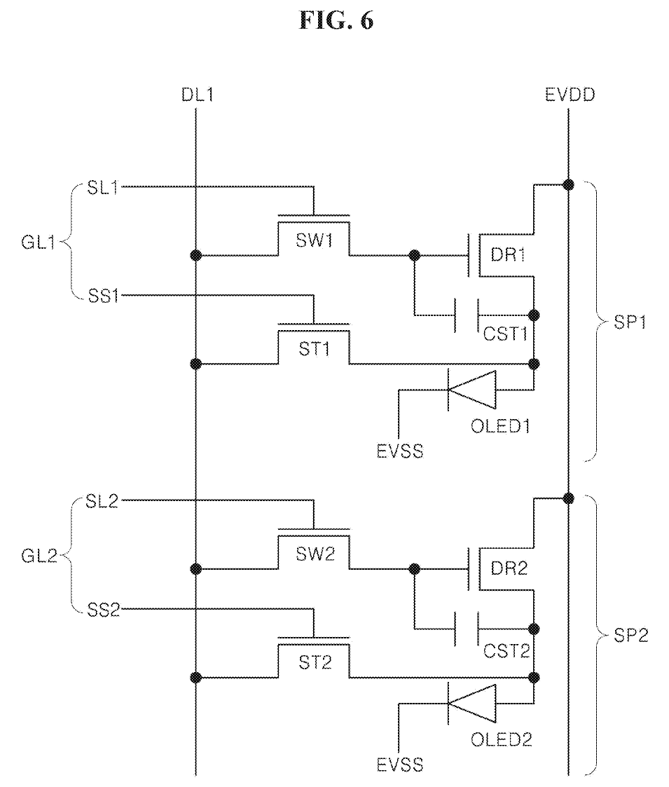

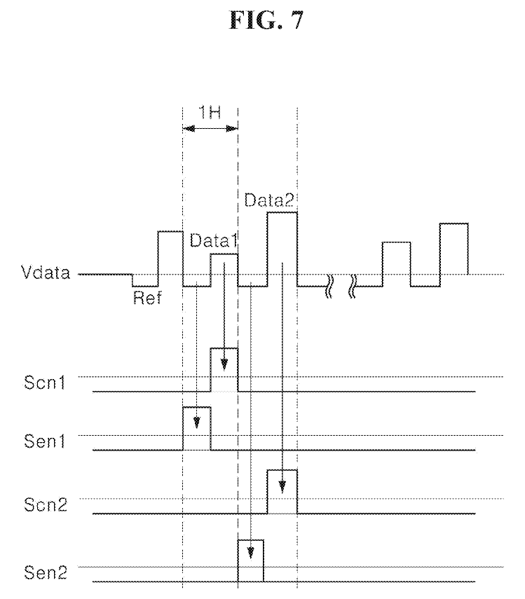

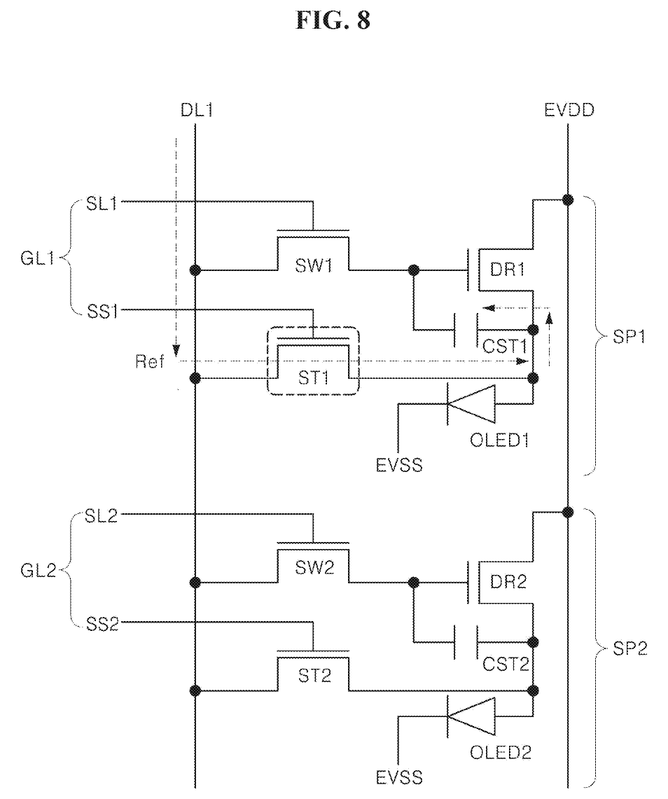

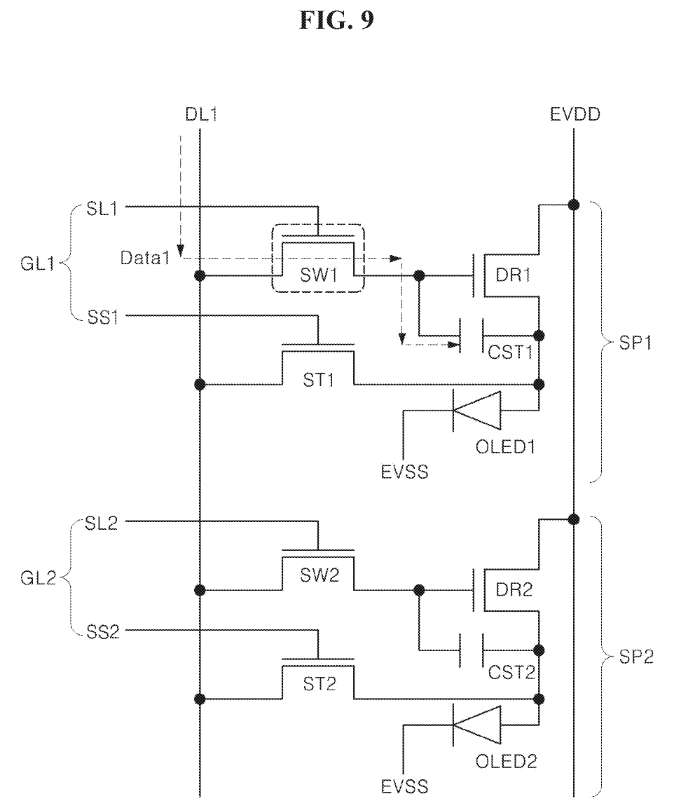

FIG. 6 is a diagram illustrating a circuit configuration of each of a first subpixel and a second subpixel according to the first embodiment of the present disclosure, FIG. 7 is a diagram illustrating a driving waveform of each of the first subpixel and the second subpixel illustrated in FIG. 6, and FIGS. 8 and 9 are diagrams illustrating an operating state of the first subpixel, based on the driving waveform illustrated in FIG. 7.

As illustrated in FIG. 6, a first subpixel SP1 and a second subpixel SP2 may be respectively disposed in an upper portion and a lower portion in a vertical direction in a display panel. The first subpixel SP1 may be defined by a first gate line GL1, a first data line DL1, a high-level voltage line EVDD, and a low-level voltage line EVSS. The second subpixel SP2 may be defined by a second gate line GL2, the first data line DL1, the high-level voltage line EVDD, and the low-level voltage line EVSS.

The first subpixel SP1 may include a first switching transistor SW1, a first sensing transistor ST1, a first driving transistor DR1, a first capacitor CST1, and a first light emitting diode OLED1. The second subpixel SP2 may include a second switching transistor SW2, a second sensing transistor ST2, a second driving transistor DR2, a second capacitor CST2, and a second light emitting diode OLED2.

The first subpixel SP1 and the second subpixel SP2 may be disposed in the vertical direction in the display panel, and thus, may have the same configuration and the same connection relationship and may operate at different times, based on the first gate line GL1 and the second gate line GL2. This will be described below.

As illustrated in FIGS. 4, 7, and 8, the first sensing transistor ST1 of the first subpixel SP1 may be turned on based on a first sensing signal Sen1 of a high voltage for a first time. The first time may be a time corresponding to half of one horizontal time 1H, but is not limited thereto. A selection switch SEL of a data driver 140 may connect the first data line DL1 to a voltage output circuit 141 for the first time for which the first sensing transistor ST1 is turned on.

The data driver 140 may drive the voltage output circuit 141 so that a reference voltage Ref is output through the first data line DL1, for the first time for which the first sensing transistor ST1 is turned on. The reference voltage Ref may be applied through the first data line DL1 and may be transferred to the second electrode of the first capacitor CST1 via the turned-on first sensing transistor ST1.

As illustrated in FIGS. 4, 7, and 9, the first switching transistor SW1 of the first subpixel SP1 may be turned on based on a first scan signal Scn1 of a high voltage for a second time. The second time may be a time corresponding to the other half of one horizontal time 1H, but is not limited thereto. The selection switch SEL of the data driver 140 may connect the first data line DL1 to the voltage output circuit 141 for the second time for which the first switching transistor SW1 is turned on.

The data driver 140 may drive the voltage output circuit 141 so that a first data voltage Data1 is output through the first data line DL1, for the second time for which the first switching transistor SW1 is turned on. The first data voltage Data1 may be applied through the first data line DL1 and may be transferred to the first electrode of the first capacitor CST1 via the turned-on first switching transistor SW1.

When the first scan signal Scn1 of a high voltage is changed to the first scan signal Scn1 of a low voltage for a third time, the first driving transistor DR1 of the first subpixel SP1 may generate a first driving current, and the first light emitting diode OLED1 of the first subpixel SP1 may emit light, based on the first driving current. At this time, the first driving transistor DR1 of the first subpixel SP1 may generate the first driving current, based on a voltage difference between the reference voltage Ref transferred through the second electrode of the first capacitor CST1 and the first data voltage Data1 transferred through the first electrode of the first capacitor CST1.

Moreover, the second subpixel SP2 disposed in a next line with respect to the first subpixel SP1 may operate based on the same method as the first subpixel SP1, and this will be briefly described below.

When the first scan signal Scn1 of a high voltage is changed to the first scan signal Scn1 of a low voltage, a second sensing signal Sen2 of a high voltage may be generated. When the second sensing signal Sen2 of a high voltage is generated, the second subpixel SP2 may be supplied with the reference voltage Ref.

Subsequently, when the second sensing signal Sen2 of a high voltage is changed to the second sensing signal Sen2 of a low voltage, a second scan signal Scn2 of a high voltage may be generated. When the second scan signal Scn2 of a high voltage is generated, the second subpixel SP2 may be supplied with a second data voltage Data2.

Subsequently, when the second scan signal Scn2 of a high voltage is changed to the second scan signal Scn2 of a low voltage, the second driving transistor DR2 of the second subpixel SP2 may generate a second driving current, and the second light emitting diode OLED2 of the second subpixel SP2 may emit light, based on the second driving current.

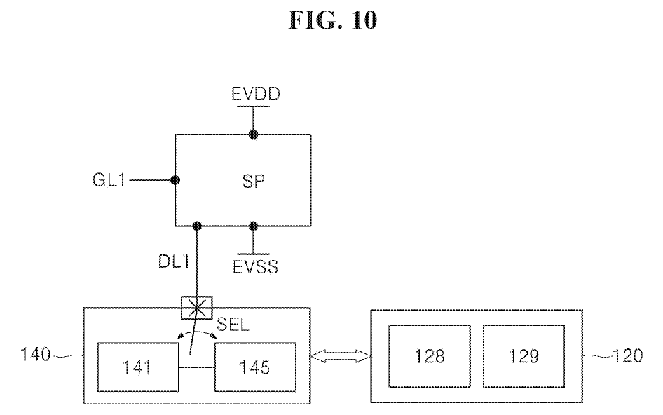

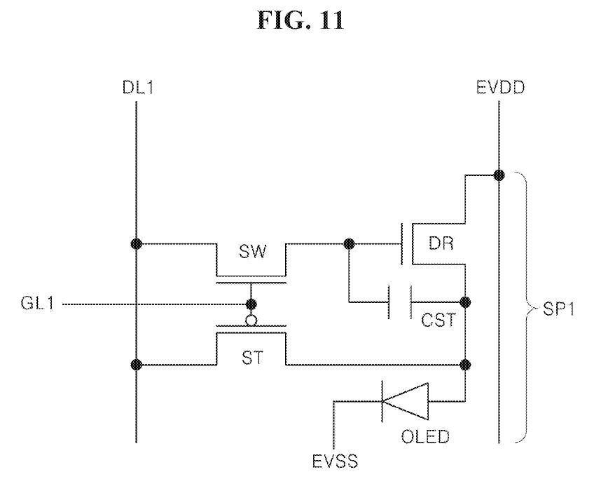

FIG. 10 is a diagram for describing some of elements of a light emitting display apparatus according to a second embodiment of the present disclosure, and FIG. 11 is a diagram illustrating a circuit configuration of a subpixel according to a second embodiment of the present disclosure.

As illustrated in FIG. 10, a subpixel SP according to the second embodiment may be defined by a first gate line GL1, a high-level voltage line EVDD, a low-level voltage line EVSS, and a first data line DL1. Except for that the first gate line GL1 does not include a plurality of signal lines, the subpixel SP according to the second embodiment may be the same as the subpixel according to the first embodiment. Also, a data driver 140 according to the second embodiment may be the same as the data driver according to the first embodiment. Therefore, descriptions relevant thereto may refer to the first embodiment.

As illustrated in FIG. 11, a subpixel SP1 according to the second embodiment may include a switching transistor SW, a sensing transistor ST, a driving transistor DR, a capacitor CST, and a light emitting diode OLED. Hereinafter, in the second embodiment, an example where a switching transistor SW implemented as an n type and a sensing transistor ST implemented as a p type are configured as a CMOS (Complementary Metal Oxide Semiconductor) type will be described. However, this may be merely one embodiment, and on the contrary, a switching transistor SW implemented as a p type and a sensing transistor ST implemented as an n type may be configured.

The switching transistor SW may include a gate electrode connected to a first gate line GL1, a first electrode connected to a first data line DL1, and a second electrode connected to a gate electrode of the driving transistor DR and a first electrode of the capacitor CST. The switching transistor SW may be turned on based on a first gate signal of a first voltage applied through the first gate line GL1 and may transfer a data voltage, applied through the first data line DL1, to the first electrode of the capacitor CST.

The sensing transistor ST may include a gate electrode connected to the first gate line GL1, a first electrode connected to the first data line DL1, and a second electrode connected to a second electrode of the driving transistor DR, a second electrode of the capacitor CST, and an anode electrode of the light emitting diode OLED. The sensing transistor ST may be turned on based on a first gate signal of a second voltage applied through the first gate line GL1 and may transfer a reference voltage, applied through the first data line DL1, to a sensing node connected to the second electrode of the driving transistor DR, the second electrode of the capacitor CST, and the anode electrode of the light emitting diode OLED. The sensing transistor ST may be turned on to sense a threshold voltage of the driving transistor DR or a threshold voltage of the light emitting diode OLED through the sensing node during a separately defined sensing driving period.

The driving transistor DR may include a gate electrode connected to the second electrode of the switching transistor SW and the first electrode of the capacitor CST, a second electrode connected to a high-level voltage line EVDD, and a second electrode connected to the second electrode of the capacitor CST, the second electrode of the sensing transistor ST, and the anode electrode of the light emitting diode OLED. The driving transistor DR may be turned on based on a data voltage stored in the capacitor CST and may generate a driving current.

The capacitor CST may include the first electrode connected to the second electrode of the switching transistor SW and the gate electrode of the driving transistor DR and the second electrode connected to the second electrode of the driving transistor DR, the second electrode of the sensing transistor ST, and the anode electrode of the light emitting diode OLED. The capacitor CST may apply the data voltage, stored therein, to the gate electrode of the driving transistor DR.

The light emitting diode OLED may include the anode electrode connected to the second electrode of the capacitor CST, the second electrode of the sensing transistor ST, and the second electrode of the driving transistor DR and a cathode electrode connected to a low-level voltage line EVSS. The light emitting diode OLED may emit light, based on the driving current generated from the driving transistor DR.

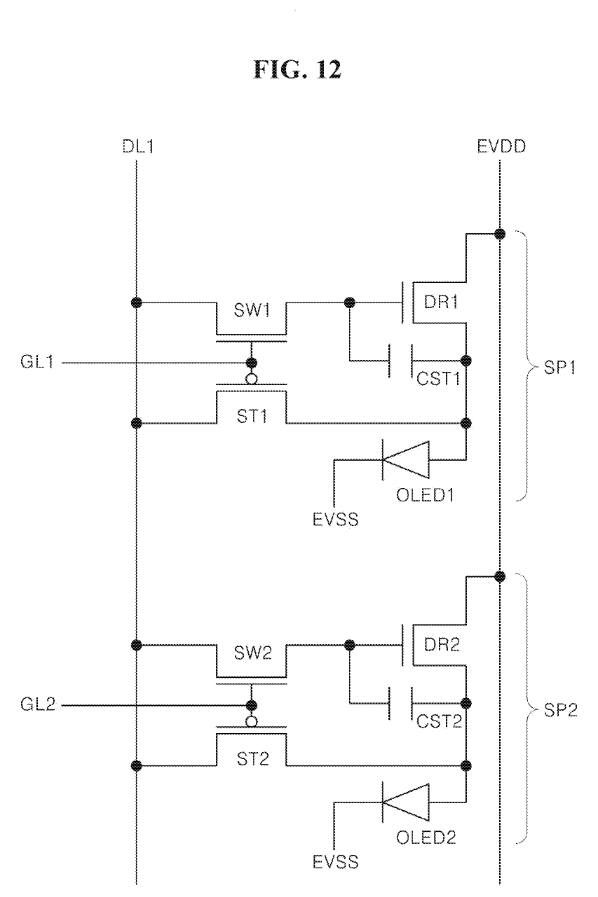

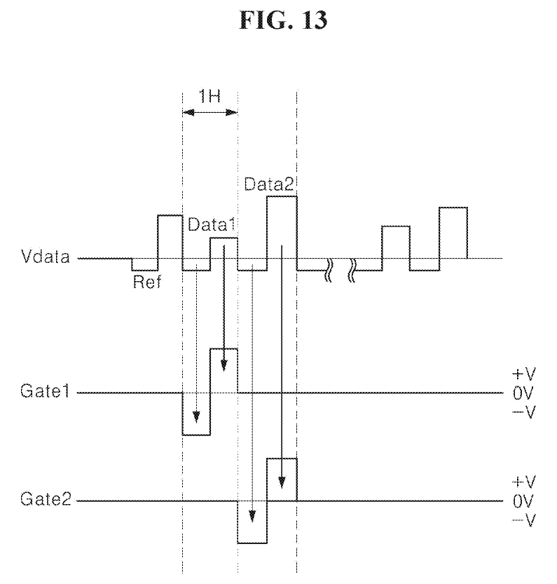

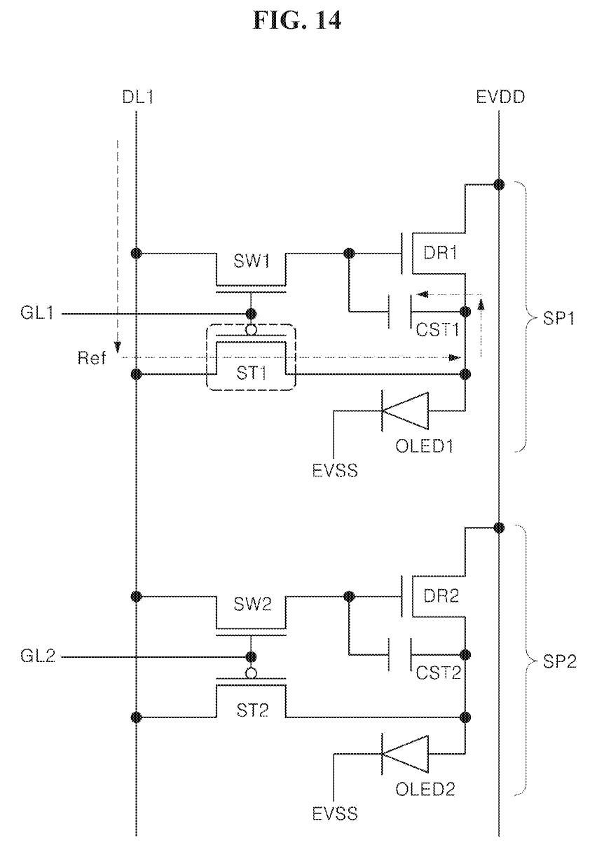

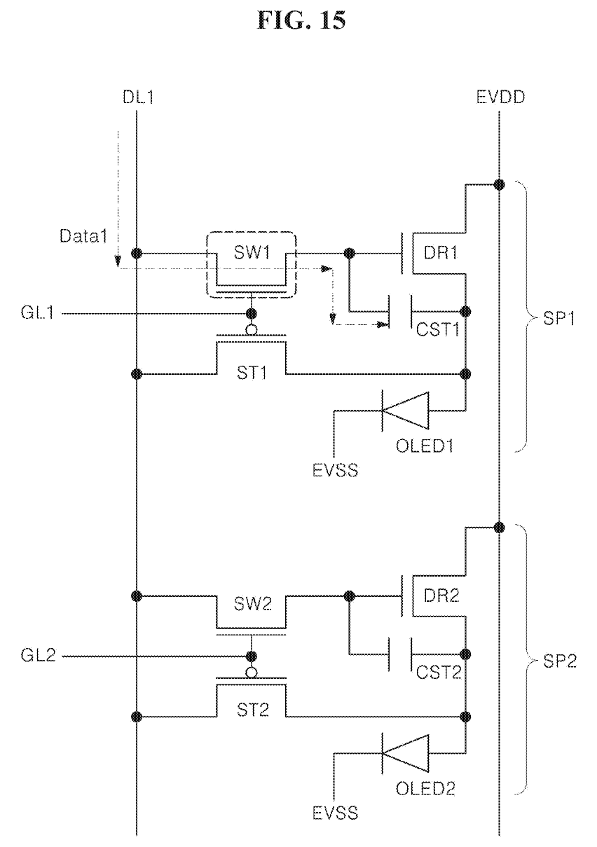

FIG. 12 is a diagram illustrating a circuit configuration of each of a first subpixel and a second subpixel according to the second embodiment of the present disclosure, FIG. 13 is a diagram illustrating a driving waveform of each of the first subpixel and the second subpixel illustrated in FIG. 12, and FIGS. 14 and 15 are diagrams illustrating an operating state of the first subpixel, based on the driving waveform illustrated in FIG. 13.

As illustrated in FIG. 12, a first subpixel SP1 and a second subpixel SP2 may be respectively disposed in an upper portion and a lower portion in a vertical direction in a display panel. The first subpixel SP1 may be defined by a first gate line GL1, a first data line DL1, a high-level voltage line EVDD, and a low-level voltage line EVSS. The second subpixel SP2 may be defined by a second gate line GL2, the first data line DL1, the high-level voltage line EVDD, and the low-level voltage line EVSS.

The first subpixel SP1 may include a first switching transistor SW1, a first sensing transistor ST1, a first driving transistor DR1, a first capacitor CST1, and a first light emitting diode OLED1. The second subpixel SP2 may include a second switching transistor SW2, a second sensing transistor ST2, a second driving transistor DR2, a second capacitor CST2, and a second light emitting diode OLED2.

The first subpixel SP1 and the second subpixel SP2 may be disposed in the vertical direction in the display panel, and thus, may have the same configuration and the same connection relationship and may operate at different times, based on the first gate line GL1 and the second gate line GL2. This will be described below.

As illustrated in FIGS. 10, 13, and 14, the first sensing transistor ST1 of the first subpixel SP1 may be turned on based on a first gate signal Gate1 of a second voltage (-V which is a negative voltage) for a first time. The first time may be a time corresponding to half of one horizontal time 1H, but is not limited thereto. A selection switch SEL of a data driver 140 may connect the first data line DL1 to a voltage output circuit 141 for the first time for which the first sensing transistor ST1 is turned on.

The data driver 140 may drive the voltage output circuit 141 so that a reference voltage Ref is output through the first data line DL1, for the first time for which the first sensing transistor ST1 is turned on. The reference voltage Ref may be applied through the first data line DL1 and may be transferred to the second electrode of the first capacitor CST1 via the turned-on first sensing transistor ST1.

As illustrated in FIGS. 10, 13, and 15, the first switching transistor SW1 of the first subpixel SP1 may be turned on based on a first gate signal Gate1 of a first voltage (+V which is a positive voltage) for a second time. The second time may be a time corresponding to the other half of one horizontal time 1H, but is not limited thereto. The selection switch SEL of the data driver 140 may connect the first data line DL1 to the voltage output circuit 141 for the second time for which the first switching transistor SW1 is turned on.

The data driver 140 may drive the voltage output circuit 141 so that a first data voltage Data1 is output through the first data line DL1, for the second time for which the first switching transistor SW1 is turned on. The first data voltage Data1 may be applied through the first data line DL1 and may be transferred to the first electrode of the first capacitor CST1 via the turned-on first switching transistor SW1.

When the first gate signal Gate1 of the first voltage (+V which is a positive voltage) is changed to a first gate signal Gate1 of a third voltage (0 V which is a ground voltage) for a third time, the first driving transistor DR1 of the first subpixel SP1 may generate a first driving current, and the first light emitting diode OLED1 of the first subpixel SP1 may emit light, based on the first driving current. At this time, the first driving transistor DR1 of the first subpixel SP1 may generate the first driving current, based on a voltage difference between the reference voltage Ref transferred through the second electrode of the first capacitor CST1 and the first data voltage Data1 transferred through the first electrode of the first capacitor CST1.

Moreover, the second subpixel SP2 disposed next to the first subpixel SP1 may operate based on the same method as the first subpixel SP1, and this will be briefly described below.

When the first gate signal Gate1 of the first voltage (+V which is a positive voltage) is changed to the third voltage (0 V which is a ground voltage), the second gate signal Gate2 of the second voltage (-V which is a negative voltage) may be generated. When the second gate signal Gate2 of the second voltage is generated, the second subpixel SP2 may be supplied with the reference voltage Ref.

Subsequently, when the second gate signal Gate2 of the second voltage is changed to a second gate signal Gate2 of a first voltage (+V which is a positive voltage), the second subpixel SP2 may be supplied with the second data voltage Data2.

Subsequently, when a second gate signal Gate2 of a first voltage is changed to a second gate signal Gate2 of a third voltage (0 V which is a ground voltage), the second driving transistor DR2 of the second subpixel SP2 may generate the second driving current, and the second light emitting diode OLED2 of the second subpixel SP2 may emit light, based on the second driving current.

Furthermore, advantages of a case where the first sensing transistor ST1 and the first switching transistor SW1 are implemented as a CMOS type will be described below.

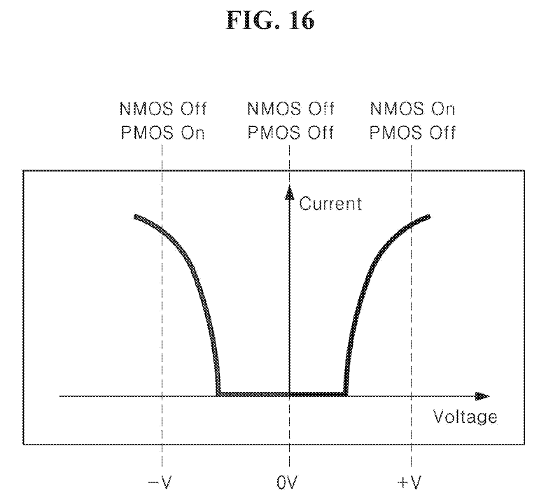

FIG. 16 is a diagram for describing a characteristic of a transistor according to the second embodiment of the present disclosure.

As illustrated in FIG. 16, according to the second embodiment, a sensing transistor may be implemented as a PMOS (P channel MOS) type, and a switching transistor may be implemented as an NMOS (N channel MOS) type. That is, the sensing transistor and the switching transistor may be implemented as a CMOS type. In this case, CMOS may be implemented as an oxide semiconductor and a low temperature polysilicon (LTPS) semiconductor, but is not limited thereto.

According to the second embodiment, a layer configuring an oxide semiconductor may differ from a layer configuring an LTPS semiconductor. Therefore, in a thin film process included in a manufacturing process of a display panel, a threshold voltage may be controlled (Vth shift based on process control) so that an NMOS transistor is turned on (NMOS on) based on a first voltage (+V), a PMOS transistor is turned on (PMOS on) based on a second voltage (-V), and the NMOS transistor and the PMOS transistor are simultaneously turned off (NMOS off, PMOS off) based on a third voltage (0 V).

A transistor implemented as a CMOS transistor may perform different operations, based on the voltage conditions described above, and a level of the first voltage (+V), a level of the second voltage (-V), and a level of the third voltage (0V) may be shifted in a process control operation.

In addition, according to the second embodiment, when one of an NMOS transistor and a PMOS transistor is turned on, the other transistor may be turned off based on an opposite voltage condition, and thus, a degradation characteristic of a transistor operating as a switch type may be delayed, thereby contributing to enhance a lifetime of a device.

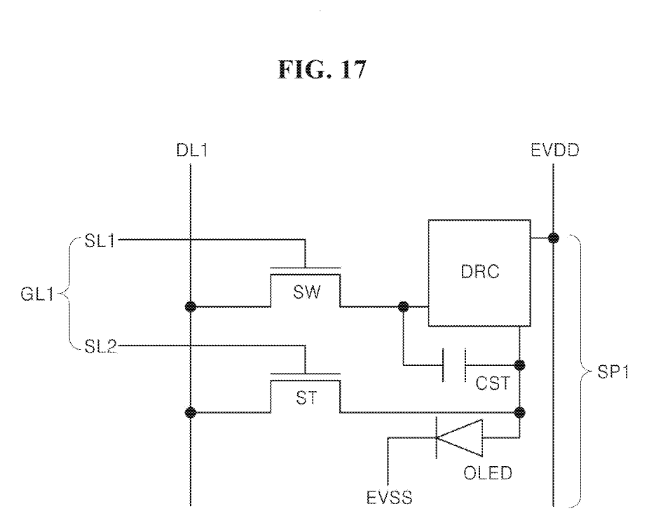

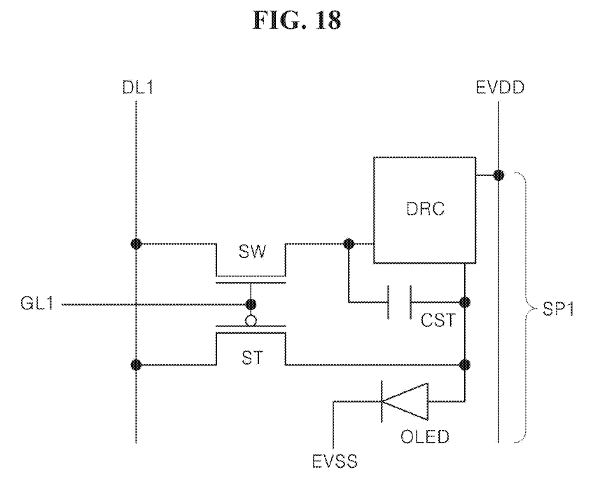

FIGS. 17 and 18 are diagrams for describing a modification example of a subpixel according to a third embodiment of the present disclosure.

As illustrated in FIG. 17, a subpixel SP1 according to the third embodiment may be configured as the first embodiment, but there may be a difference in that the subpixel SP1 includes a pixel circuit DRC. Also, as illustrated in FIG. 18, a subpixel SP1 according to the third embodiment may be configured as the second embodiment, but there may be a difference in that the subpixel SP1 includes a pixel circuit DRC.

According to the third embodiment, the pixel circuit DR may further include a driving transistor which generates a driving current and a compensation transistor or a compensation capacitor for compensating for a threshold voltage. Also, the pixel circuit DRC may further include a driving transistor which generates a driving current and an emission control transistor for controlling an emission time of a light emitting diode. Also, the pixel circuit DRC may further include a driving transistor which generates a driving current and a voltage control transistor for applying an initialization voltage or a bias voltage to a specific node.

Hereinabove, the present disclosure may enhance an aperture ratio, based on a subpixel dualizing and receiving a data voltage and a reference voltage through one data line, and thus, may enhance the lifetime and display quality of a display panel. Also, the present disclosure may delay a degradation characteristic of a transistor so that, when one of two transistors is turned on, the other transistor is turned off based on an opposite voltage condition, thereby contributing to enhance a lifetime of a device.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A display apparatus, comprising:
a display panel including a subpixel; and
a driver configured to drive the display panel,
wherein the subpixel comprises:
a sensing transistor configured to transfer a reference voltage, applied through a data line, to a second electrode of a capacitor for a first time included in a horizontal period; and
a switching transistor configured to transfer a data voltage, applied through the data line, to a first electrode of the capacitor for a second time included in the horizontal period.

2. The display apparatus of claim 1, wherein the sensing transistor comprises a first electrode connected to the data line, a gate electrode connected to a first sensing line included in a first gate line, and a second electrode connected to the second electrode of the capacitor, and
wherein the switching transistor comprises a first electrode connected to the data line, a gate electrode connected to a first scan line included in the first gate line, and a second electrode connected to the first electrode of the capacitor.

3. The display apparatus of claim 2, wherein the subpixel further comprises:
a driving transistor including a gate electrode connected to the second electrode of the switching transistor and the first electrode of the capacitor, a first electrode connected to a high-level voltage line, and a second electrode connected to the second electrode of the capacitor and the second electrode of the sensing transistor; and
a light emitting diode including an anode electrode and a cathode electrode, the anode electrode connected to the second electrode of the sensing transistor, the second electrode of the driving transistor, and the second electrode of the capacitor, the cathode electrode connected to a low-level voltage line.

4. The display apparatus of claim 1, wherein the sensing transistor and the switching transistor have a period where operations opposite to each other are performed in response to a first gate signal applied through a first gate line.

5. The display apparatus of claim 1, wherein the sensing transistor and the switching transistor have a period where the sensing transistor and the switching transistor are simultaneously turned off in response to a first gate signal applied through a first gate line.

6. The display apparatus of claim 4, wherein each of the sensing transistor and the switching transistor is implemented as a CMOS type including a PMOS type and an NMOS type, wherein the sensing transistor is implemented as one of the PMOS type and the NMOS type, and wherein the switching transistor is implemented as the other of the PMOS type and the NMOS type.

7. The display apparatus of claim 4, wherein the sensing transistor comprises a first electrode connected to the data line, a gate electrode connected to the first gate line, and a second electrode connected to the second electrode of the capacitor, and
wherein the switching transistor comprises a first electrode connected to the data line, a gate electrode connected to the first gate line, and a second electrode connected to the first electrode of the capacitor.

8. The display apparatus of claim 7, wherein the sensing transistor is turned on based on the first gate signal of a second voltage applied through the first gate line,
wherein the switching transistor is turned on based on the first gate signal of a first voltage applied through the first gate line,
wherein the sensing transistor and the switching transistor are simultaneously turned off based on the first gate signal of a third voltage applied through the first gate line, and
wherein the first voltage, the second voltage, and the third voltage have different levels.

9. A driving method of a display apparatus, the driving method comprising:
turning on a sensing transistor to transfer a reference voltage, applied through a data line, to a second electrode of a capacitor for a first time included in a horizontal period;
turning on a switching transistor to transfer a data voltage, applied through the data line, to a first electrode of the capacitor for a second time included in the horizontal period; and
driving a driving transistor, based on a voltage difference between the data voltage stored in the capacitor and the reference voltage, and allowing a light emitting diode to emit light, based on a driving current generated from the driving transistor.

10. The driving method of claim 9, wherein the sensing transistor comprises a first electrode connected to the data line, a gate electrode connected to a first sensing line included in a first gate line, and a second electrode connected to the second electrode of the capacitor, and
wherein the switching transistor comprises a first electrode connected to the data line, a gate electrode connected to a first scan line included in the first gate line, and a second electrode connected to the first electrode of the capacitor.

11. The driving method of claim 9, wherein the sensing transistor comprises a first electrode connected to the data line, a gate electrode connected to a first gate line, and a second electrode connected to the second electrode of the capacitor, and
wherein the switching transistor comprises a first electrode connected to the data line, a gate electrode connected to the first gate line, and a second electrode connected to the first electrode of the capacitor.

12. The driving method of claim 11, wherein the sensing transistor is turned on based on a first gate signal of a second voltage applied through the first gate line,
wherein the switching transistor is turned on based on the first gate signal of a first voltage applied through the first gate line,
wherein the sensing transistor and the switching transistor are simultaneously turned off based on the first gate signal of a third voltage applied through the first gate line, and
wherein the first voltage, the second voltage, and the third voltage have different levels.

13. The driving method of claim 10, wherein:
the driving transistor includes a gate electrode connected to the second electrode of the switching transistor and the first electrode of the capacitor, a first electrode connected to a high-level voltage line, and a second electrode connected to the second electrode of the capacitor and the second electrode of the sensing transistor; and
the light emitting diode includes an anode electrode connected to the second electrode of the sensing transistor, the second electrode of the driving transistor, and the second electrode of the capacitor and a cathode electrode connected to a low-level voltage line.
